(19) United States
(12) Patent Application Publication
(10) Pub. No.: US 2026/0068187 A1
(43) Pub. Date: Mar. 5, 2026

(54) METHODS OF FORMING A SEMICONDUCTOR STACK ON A SUBSTRATE INCLUDING A SEMIMETAL LINER

(71) Applicant: ASM IP Holding B.V., Almere (NL)

(72) Inventors: Alessandra Leonhardt, Sipoo (FI); Vivek Koladi Mootheri, Leuven (BE); Ranjith Karuparambil Ramachandran, Leuven (BE); Andrea Illiberi, Leuven (BE); Leo Lukose, Leuven (BE); Lorenzo Bottiglieri, Phoenix, AZ (US)

(21) Appl. No.: 19/313,425

(22) Filed: Aug. 28, 2025

Related U.S. Application Data
(60) Provisional application No. 63/689,328, filed on Aug. 30, 2024.

(51) Int. Cl. H10D 1/00; H01L 21/02; H10D 1/62; H10D 62/10

(52) U.S. Cl. CPC H10D 1/025; H10D 62/102; H10D 1/62

(57) ABSTRACT

A semimetal liner and a metal-insulator-metal (MIM) capacitor (MIMCAP) are described along with the methods of manufacture or fabrication. The MIM capacitor structure includes a liner formed of a thin layer or film of a semimetal, which is a few nanometers thick, e.g., a thickness in the range of about 0.5 nm to about 5 nm or more. The semimetal liner is sandwiched between an electrode layer and a dielectric layer, e.g., a layer of high or ultra-high-k material, thereby providing a cap for the electrode to limit leakage currents in the structure.

### CROSS-REFERENCE TO RELATED APPLICATION(S)

This Application claims the benefit of U.S. Provisional Application 63/689,328 filed on Aug. 30, 2024, the entire contents of which are incorporated herein by reference.

### FIELD

The present disclosure relates generally to design and manufacture of capacitors for use in electronics including in memory devices such as DRAM (Dynamic Random Access Memory), SRAM (Static Random Access Memory), and the like, and, more particularly, to manufacture of liners for electronic devices and to manufacture of metal-insulator-metal (MIM) capacitors (often labeled “MIMCAPS”) with enhanced leakage current characteristics for use in memory and other electronic or computer devices.

### BACKGROUND

DRAM and other memory devices can utilize capacitors to store bits of information within an integrated circuit. Such capacitors capacitor can be formed by placing a dielectric material between two electrodes formed of conductive materials. With reductions in device sizes and spacing, DRAM devices often use MIM capacitors in which the electrode materials are metals. These electrode materials generally have higher conductivities than other electrode materials such as semiconductors and also have various work functions, have improved stability, and exhibit reduced depletion effects.

The electrode materials are commonly chosen to have high conductivity to ensure fast device speeds, and MIMs also typically utilize insulating materials having a dielectric constant or k-value much higher than that of SiO₂, with such dielectric materials being classified as high-k materials or ultra-high-k materials. Unfortunately, increasing the k-value can decrease the conduction band offset with respect to the metal electrode, which can lead to unwanted leakage current for a MIM device especially at elevated temperatures.

There remains a demand for MIM capacitor designs for use in DRAM and other devices with reduced leakage current. To this end, the electrodes have a strong impact in the leakage conduction in MIM capacitors. For example, electrodes can influence leakage currents in the following ways: (a) by directly injecting electrons over the conduction band of the dielectric materials, if the energy difference between the conduction band of the dielectric and the work function of the metal is too small; (b) by allowing electrons to tunnel through the dielectric material; and (c) by scavenging oxygen from the dielectric materials, which generates oxygen vacancies and, thus, increases the trap density. Thus, there is a need for innovative manufacturing techniques that can produce advanced MIM capacitors at large scale while maintaining high-quality electrical properties, complying with stringent thermal budgets, and remaining cost-effective for high-volume production.

### BRIEF SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments provide a method of forming a semiconductor stack on a substrate for use in metal-insulator-metal (MIM) capacitors, the method comprising: forming a first electrode layer comprising a conductive material on the substrate; forming a first semimetal layer on the first electrode layer; and forming a dielectric layer on the first semimetal layer; wherein the first semimetal layer forms a first liner between the first electrode layer and the dielectric layer.

In some embodiments, the first semimetal layer is an elemental semimetal layer.

In some embodiments, the first electrode layer, the first semimetal layer, and the dielectric layer are formed by atomic layer deposition processes.

In some embodiments, the atomic layer deposition of the first electrode layer, the first semimetal layer, and the dielectric layer is performed within the same semiconductor processing apparatus.

In some embodiments, the atomic layer deposition of the first electrode layer, the first semimetal layer, and the dielectric layer is performed within a first reaction chamber without breaking vacuum.

In some embodiments, the first semimetal layer comprises antimony, bismuth, or tellurium.

In some embodiments, forming the first semimetal layer comprises: depositing a first metal oxide layer on the first electrode layer by an atomic layer deposition process; and performing a post-deposition thermal treatment on the first metal oxide layer in a reducing atmosphere to convert the first metal oxide layer to the first semimetal layer.

In some embodiments, the atomic layer deposition of the first electrode layer, the first metal oxide layer, and the dielectric layer, and the post-deposition thermal treatment of the first metal oxide layer are performed within a first reaction chamber without breaking vacuum.

In some embodiments, the first semimetal layer comprises alpha-tin (α-Sn).

In some embodiments the method further comprises: forming a second semimetal layer on the dielectric layer; and forming a second electrode layer on the second semimetal layer; wherein the second semimetal layer forms a second liner between the dielectric layer and the second electrode layer.

In some embodiments, the first electrode layer, the first semimetal layer, the dielectric layer, the second semimetal layer, and the second semimetal layer are formed by atomic layer deposition processes in a first reaction chamber without breaking vacuum.

In some embodiments, the second semimetal layer comprises an elemental semimetal layer.

In some embodiments, the second semimetal layer comprises antimony, bismuth, or tellurium.

In some embodiments, forming the second semimetal layer further comprises: depositing a second metal oxide layer on the dielectric layer by an atomic layer deposition process; and performing a post-deposition thermal treatment on the second metal oxide layer in a reducing atmosphere to convert the second metal oxide layer to the second semimetal layer.

In some embodiments, the dielectric layer comprises a hafnium zirconium oxide (HfZrO) dielectric layer.

In some embodiments, the hafnium zirconium oxide (HfZrO) dielectric layer is formed by performing one or super-cycles of an atomic layer deposition process, each super-cycle comprising: performing one or more repetitions of a hafnium oxide sub-cycle; and performing one or more repetitions of a zirconium oxide sub-cycle; wherein the hafnium zirconium oxide layer (HfZrO) dielectric layer has a stoichiometry (Hf:Zr) between 1:1 and 1:5.

Various embodiments provide a method of forming a semiconductor stack on a substrate for use in metal-insulator-metal (MIM) capacitors, the method comprising: depositing a first electrode layer comprising a conductive material on the substrate; forming a first semimetal layer directly on the first electrode layer; depositing a hafnium zirconium oxide (HfZrO) dielectric layer directly on the first semimetal layer; forming a second semimetal layer directly on the hafnium zirconium oxide (HfZrO) dielectric layer; and depositing a second electrode layer directly on the second semimetal layer; wherein the first semimetal layer forms a first liner between the first electrode layer and the hafnium zirconium oxide dielectric layer and the second semimetal layer forms a second liner between the hafnium zirconium oxide (HfZrO) dielectric layer and the second electrode layer.

In some embodiments, the first semimetal layer and the second semimetal layer comprise a material selected from the group consisting of antimony, bismuth, tellurium, and alpha-tin (α-Sn).

In some embodiments, the semiconductor stack is formed by atomic layer deposition processes within a first reaction chamber without breaking vacuum.

In some embodiments, the first semimetal layer and the second semimetal layer are alpha-tin (α-Sn) are formed by: depositing a first tin oxide layer on the first electrode layer by an atomic layer deposition process; depositing a second tin oxide layer on the hafnium zirconium dielectric layer; and performing a post-deposition thermal treatment on the first tin oxide layer and second tin oxide layer in a reducing atmosphere to convert the first tin oxide layer and a first alpha-tin (first α-Sn) semimetal layer and to convert the second tin oxide layer to a second alpha-tin (second α-Sn) semimetal layer.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWINGS

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 illustrates a method of forming a semiconductor stack on a substrate for use in metal-insulator-metal (MIM) capacitors in accordance with one or more embodiments of the present disclosure.

FIG. 2 illustrates a simplified cross-sectional view of a substrate upon which a semiconductor stack can be formed in accordance with one or more embodiments of the present disclosure.

FIG. 3-7 illustrate simplified cross-section views of structures and semiconductor stacks formed by the one or more embodiments of the present disclosure.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. The substrate can include various topologies, such as gaps, including recesses, lines, trenches, or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “layer” and/or “film” can used interchangeably and can refer to any continuous or non-continuous structure and material, such as material deposited by the methods disclosed herein. For example, a layer can include two-dimensional materials, three-dimensional materials, nanoparticles, partial or full molecular layers or partial or full atomic layers or clusters of atoms and/or molecules. A layer may partially or wholly consist of a plurality of dispersed atoms on a surface of a substrate and/or embedded in a substrate and/or embedded in a device manufactured on that substrate. A layer may comprise material or a layer with pinholes and/or isolated islands. A layer may be at least partially continuous. A layer may be patterned, e.g., subdivided, and may be comprised of a plurality of semiconductor devices.

As used herein, the term “cyclic deposition process” or “cyclical deposition process” can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. In some cases, a cyclical deposition process can include continually flowing one or more precursors, reactants, or inert gases, and pulsing other of the precursors or reactants.

As used herein, the term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, when performed with alternating pulses of precursor(s)/reactive gas(es), and purge (e.g., inert carrier) gas(es). Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber.

As used herein, the term “chemical vapor deposition” (CVD) may refer to any process wherein a substrate is exposed to one or more volatile precursors, which react and/or decompose on a substrate surface to produce a desired deposition.

As described in greater detail below, various details and embodiments of the disclosure may be utilized in conjunction with a reaction chamber configured for a multitude of deposition processes, including but not limited to, ALD, CVD, metalorganic chemical vapor deposition (MOCVD), molecular beam epitaxy (MBE), physical vapor deposition (PVD), plasma-enhanced chemical vapor deposition (PECVD), and plasma etching. The embodiments of the disclosure may also be utilized in semiconductor processing systems configured for depositing (providing or forming) layers or thin films of a MIM capacitor, which are known by (or yet to be developed by) those skilled in the arts.

As used herein, the term “semimetal” and “semimetal layer” may refer to a material that has an energy band dispersion which is different from elemental metal layers. For example, as used herein, the term “semimetals” and “semimetal layers” may refer to a material whose density of states at the Fermi level reduces to zero. As a further example, as used herein, the term “semimetal” and “semimetal layer” may refer to a material whose energy band dispersion near the Fermi level is linear. As used herein, the term “semimetal” and “semimetal layers” does not refer to materials and layers comprising or consisting of silicon and germanium.

The inventors recognized that the electrodes of a MIM capacitor can have a strong impact on leakage conduction. Instead of replacing a whole MIM capacitor electrode with a semimetal to control leakage conduction, the inventors created a method of fabricating a MIM capacitor with a semimetal liner sandwiched between an electrode and the insulator or dielectric. The semimetal liner may be formed using PVD, ALD, or other deposition process.

Semimetals have a band dispersion which is different from the more common metal layers. Not to be bound by any theory—at the fermi level, the density of states in a semimetal band reduces to zero. This would indicate that there are no charge carrier states at the fermi level from which carriers can tunnel or go over the Schottky barrier to cause leakage. This reducing of the density of states at the fermi level may suppress leakage in MIM capacitors. Unlike elemental metal layers, the semimetal band dispersion near the fermi level is also linear and therefore the availability of carriers to tunnel through the dielectric layer and cause leakage is reduced. Additionally, since the liners provided are semimetal layers, they do not add additional effective oxide thickness to the entire layer stack of the MIM capacitor, thereby not significantly reducing the high dielectric constant value of the dielectric layer. Therefore, semimetal liners may reduce leakage due to carrier tunneling without adding additional equivalent oxide thickness (EOT) as result of the unique band structure of the semimetals.

The new MIM capacitors are unique, in part, due to the introduction or use of a semimetal liner instead of replacing the whole electrode with noble metals. This innovative design has a number of advantages. First, noble metals can be expensive. By using a thin (e.g., 0.5 to 5 nm) liner, the cost of using a semimetal in the MIM capacitor is greatly reduced when compared to using noble metals for the bulk electrode that may have a thickness of 20 nm or more. Second, only small process modifications are required when using a liner, as opposed to larger process modifications downstream and upstream for the whole electrode replacement. For example, in the case of etching the electrodes, the electrode metal can be etched as usual, and the liner can act as an etch stop layer. Then, a short, and different in some cases, etch cycle can be used to punch through the liner. Third, the use of semimetal liners allows capacitors to be designed so as to provide work function tuning, with less leakage through direct injection of carriers. Fourth, the liners provide capacitors with less oxygen scavenging, resulting in less leakage through trap density reduction. Fifth, the use of a semimetal liner can prevent the oxidation of the bottom electrode, which is a source of equivalent oxide thickness (EOT) increase.

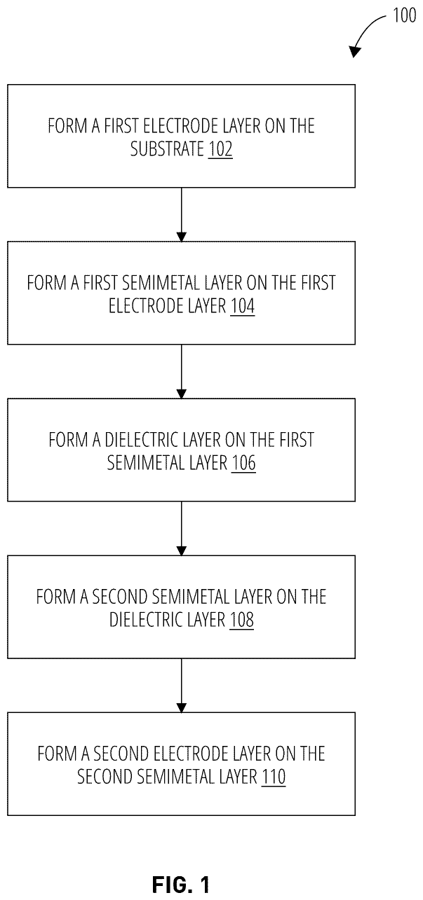

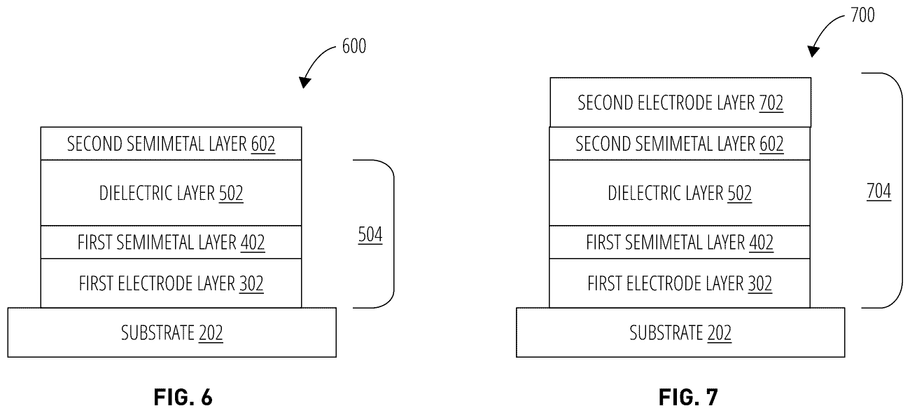

FIG. 1 illustrates an exemplary method 100 for forming a semiconductor stack on a substrate for use in metal-insulator-metal (MIM) capacitors or capacitor stack (e.g., a DRAM capacitor stack). Those skilled in the art will appreciate that each of the layers discussed herein and used in a MIM capacitor or capacitor stack may be formed using any common formation techniques such ALD (or ALD-like process or other cyclical deposition process), PVD, or CVD that are useful for deposition of thin films or layers of materials described herein. Hence, the method 100 is intended to include any useful process for depositing the layers or thin films of the MIM capacitor or capacitor stacks shown in FIG. 3 to FIG. 7.

Turning now to the figures, FIG. 1 illustrates a method 100 for forming a semiconductor stack on a substrate for use in meta-insulator metal (MIM) capacitors or capacitor stacks. In brief method 100 comprises, seating a substrate within a reaction chamber and forming a first electrode layer on the substrate (step 102), forming a first semimetal layer on the first electrode layer (step 104), and forming a dielectric layer on the first semimetal layer (step 106). In further aspects method 100 comprises forming a second semimetal layer on the dielectric layer (step 108), and forming a second electrode layer on the second semimetal layer (step 110).

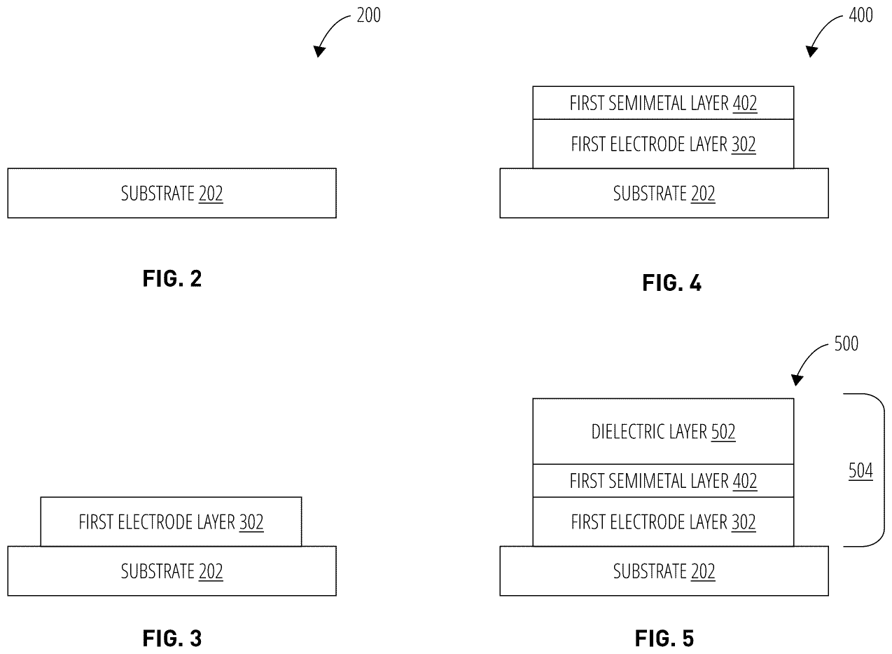

In more detail, the substrate on which the semiconductor stack is formed can include the substrates as described above and can also include a portion of a device structure, such as, a partially fabricated device structure. For example, FIG. 2 illustrates substrate 202 upon which a semiconductor stack can be formed. The substrate 202 can include a partially fabricated logic device, memory device, integrated circuit, and the like. The substrate is seated in a reaction chamber configured for deposition of the semiconductor stack. In such examples the reaction chamber can comprise a component or assembly of a single-wafer ALD reactor or a batch ALD reactor where deposition on multiple substrates takes place at the same time. In some embodiments the reaction chamber may form part of a cluster tool in which a variety of different processes for the fabrication of devices and/or integrated circuit are carried out. In some embodiments a flow-type reactor and associated reaction chamber can be utilized. In some embodiments a high-volume manufacturing-capable single wafer ALD reactor and associated reaction chamber can be used. In other embodiments a batch reactor comprising multiple substrates can be used. For embodiments in which batch ALD reactor are used, the number of substrates can be in the range of 10 to 300, in the range of 50 to 150, or in the range of 300 to 130. In addition, embodiments the substrate may be seated in other forms of reaction chamber associated with various reactors, such as, but not limited, CVD reactors, PVD reactors, PECVD reactors, PEALD reactors, and the like.

Prior to the forming the stack on the substrate (e.g., substrate 202) the substrate is heated to a desired temperature and the pressure in the reaction chamber can also be regulated to enable deposition of the semiconductor stack.

Turning again to method 100 of FIG. 1, a step 102 comprises forming a first electrode layer on the substrate. In some embodiment the first electrode layer (or bottom electrode layer) can be formed on or directly on an upper surface of the substrate. For example, FIG. 3 illustrates a structure 300 including the substrate 202 and a first electrode layer 302 disposed directly on the upper surface of the substrate 202. The first electrode layer 302 is formed by depositing a thin layer of a conductive material on the substrate. In some embodiments the first electrode layer 302 comprises a titanium nitride (TiN). The conductive first electrode layer may be formed of other metals, conductive metal oxides, conductive metal silicides, conductive metal nitrides, and combinations thereof. The purpose of the first or bottom electrode in a MIM capacitor or another device is often to serve as a primary conductor. The first electrode layer may be formed by a deposition process, such as, but not limited, to PVD, CVD, and the like. In particular embodiments the first electrode layer is deposited by an atomic layer deposition process.

In accordance with examples of the disclosure, step 104 of method 100 comprises forming a first semimetal layer on the first electrode layer 302. This may involve depositing, with PVD, ALD, or another useful deposition technology, a layer or film of a semimetal on or directly on the upper or exposed surface of the electrode formed in step 102. For example, FIG. 4 illustrates a structure 400 which includes the substrate 202 and the first electrode layer 302 as described above as well as a first semimetal layer 402 disposed on the upper surface of the first electrode layer 302.

In some implementations of the method 100, step 104 of forming the first semimetal layer comprises performing a cyclical deposition process including a plurality of deposition cycles (such as, for example, ALD, an ALD-like process, or the like). Each deposition cycle may include a precursor pulse and a reactant pulse, with the precursor pulse including exposing a substrate (e.g., the first electrode layer for step 104) to a precursor while the reactant pulse includes exposing the same substrate to a reactant.

In accordance with examples of the disclosure, the first semimetal layer 402 can comprise an elemental semimetal layer. In one aspect the first semimetal layer is formed by directly depositing an elemental semimetal layer. In another aspect the first semimetal layer is formed by depositing a metal oxide layer and subsequently employing post deposition thermal treatments to convert the metal oxide layer to the elemental semimetal layer.

In examples where the first semimetal layer is directly deposited as an elemental semimetal layer, the first semimetal layer can comprise antimony, bismuth, or tellurium. In such examples the first semimetal layer is, or consists of, or consists essentially of antimony, bismuth, tellurium, or alloys thereof. The direct deposition of the elemental first semimetal layer can be achieved by atomic layer deposition processes, although other suitable deposition process may be employed.

ALD processes for depositing a first semimetal layer comprising antimony, bismuth or tellurium can include performing a deposition cycle one or more time where each deposition cycle can include the process steps of: (a) introducing a metal precursor (e.g., a Sb-precursor, a Bi-precursor, or a Te-precursor) into the reaction chamber, and (b) introducing a reducing reactant into the reaction chamber to react with the absorbed metal precursor to form the first semimetal layer. A purge cycle can be performed after step (a) and/or step (b) to remove any excess precursor/reactants and or reactant by-products. Steps (a) and (b) of the ALD process can be repeated as needed to deposit a first semimetal layer of sufficient thickness. Further, steps (a) and (b) can be initiated and/or terminated in any order. Yet further, the ALD process for directly depositing the elemental first semimetal layer can include one or more (e.g., 1-10 or 1-5) steps (a) and/or (b) prior to proceeding to the other of step (b) or (a). It should also appreciate that the ALD process for directly depositing the first semimetal layer may include additional process steps not described herein, such as, but not limited to, cleaning steps, surface preparation steps, and the like.

Suitable metal precursor for directly depositing the first semimetal layer by ALD process can include metal containing precursors. In some embodiments the metal precursor (e.g., a Sb-precursor, Bi-precursor, or Te-precursor) can comprise one or more of a metal halide precursor, and metalorganic precursors.

In various embodiments the antimony precursor can comprise antimony chloride (SbCl₃). Other antimony precursors may be used, instead of antimony chloride or in addition to antimony chloride. Other antimony precursors may include other antimony halides. Other antimony precursors may include compounds of the form SbX₃, where X represents a halide. Other antimony precursors may include SbF₃, SbBr₃, or SbI₃. Other volatile antimony-containing compounds may be used as antimony precursors for ALD. Antimony precursors may include Sb(OCH₂CF₃)₃ and derivatives, Sb(NR₂)₃ where R represents a generalized organic group, or the like. Sb(NMe₂)₃ is an example of a specific molecule that may be used as an antimony precursor.

In various embodiments the bismuth precursor can comprise bismuth chloride (BiCl₃), bismuth amino complexes such as Bi(NMe₂)₃, other bismuth halides, or other bismuth precursors. Further bismuth precursors may include BiF₃, BiBr₃, or Bib. Bismuth precursors may include triphenylbismuth. Bismuth precursors may include aryl and alkyl derivatives of BiPh₃, such as tris(4-methylphenyl)bismuthine, tris(4-fluorophenyl)bismuthine, etc. Bismuth precursors may include Bi(OCH₂CF₃)₃. Bismuth precursors may include related alkoxides of Bi(OCH₂CF₃)₃.

In various embodiments the reducing reactant can comprise one or more of one or more of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), a hydrogen plasma, hydrogen radicals, hydrogen excited species, (e.g., C1-C4) alcohols, (e.g., C1-C4) aldehydes, (e.g., C1-C4) carboxylic acids, (e.g., B1-B12) boranes, or an amine.

In another aspect the first semimetal layer is formed by depositing a metal oxide layer and subsequently employing post deposition thermal treatments to convert the metal oxide layer to the elemental semimetal layer. As a non-limiting example step 104 of method 100 may comprise depositing a first metal oxide layer on or directly on the first electrode layer by an atomic layer deposition process, and performing a post-deposition thermal treatment on the first metal oxide layer in a reducing atmosphere to convert the first metal oxide layer to the first semimetal layer. In at least one example the first metal oxide layer can comprise a tin oxide layer (or a first tin oxide layer) deposited by an atomic layer deposition process. The ALD process for depositing the tin oxide layer may be the same or similar to those described above. For example, the ALD process for depositing the tin oxide layer may comprise (a) introducing a tin precursor into the reaction chamber, and (b) introducing an oxygen reactant into the reaction chamber to react with the absorbed tin precursor to form the tin oxide layer. A purge cycle can be performed after step (a) and/or step (b) to remove any excess precursor/reactants and or reactant by-products. Steps (a) and (b) of the ALD process can be repeated as needed to deposit the tin oxide layer to a sufficient thickness. Further, steps (a) and (b) can be initiated and/or terminated in any order. Yet further, the ALD process for depositing the first tin oxide layer can include one or more (e.g., 1-10 or 1-5) steps (a) and/or (b) prior to proceeding to the other of step (b) or (a). It should also be appreciated that the ALD process for directly depositing the tin oxide layer (i.e., the first tin oxide layer) may include additional process steps not described herein, such as, but not limited to, cleaning steps, surface preparation steps, and the like.

In various embodiments, suitable tin precursor for depositing the tin oxide layer by ALD process can include metal containing precursors. In some embodiments the tin precursor can comprise one or more of a metal halide precursor, and a metalorganic precursor. For example, the tin precursor can comprise one or more of SnCl₄, Sn(dmamb)₂, Sn(edpa)₂, Sn(ⁱPr₂fAMD)₂, Sn(N(SiMe₃)₂)₂, Sn(Ot-Amyl)₂, Sn(η₂-((N^{t}Bu)CMe₂CH₂(N^{t}Bu))), Sn(acac)₂, Sn(NMe₂)₄, and Sn(tbba).

In various embodiments suitable oxygen reactants for depositing the first metal oxide layer (e.g., a tin oxide layer or a first tin oxide layer) can include one or more of water vapor (H₂O), ozone (O₃), molecular oxygen O₂, hydrogen peroxide vapor (H₂O₂), and oxygen based plasmas including oxygen excited species generated from a plasma generating device fed with an oxygen-containing gas.

Upon deposition of the first metal oxide layer (e.g., a first tin oxide layer) the first metal oxide layer is treated to a post deposition thermal treat in a reducing atmosphere to convert the first metal oxide layer to the first semimetal layer. In various embodiments the first metal oxide layer is heated in a reaction chamber in an atmosphere including a reducing agent. In such embodiments the reducing agent can comprise hydrogen (H₂) or a carbon-containing gas (e.g., CO₂ and CH₄). In such examples the first metal oxide layer may be heated to a temperature between 500° C. and 1000° C. in a reducing atmosphere. As a non-limiting example, the first metal oxide layer can comprise a tin oxide layer and the post deposition thermal treatment in a reducing atmosphere converts the tin oxide layer to a semimetal form of tin commonly referred to as alpha-tin (α-Sn), which can also be referred to as gray tin. As opposed to metallic tin, alpha-tin (α-Sn) is allotrope having a diamond cubic structure and is semimetal material. In alternative embodiments a metallic tin layer may be deposited by ALD processes and the metallic tin may be cooled below a temperature of 13.2° C. at which temperature the metallic tin is converted to the semimetal form alpha-tin (α-Sn).

The first semimetal layer 402 is “thin” in that it has a thickness less than or equal to 5 nm with some embodiments of method 100 depositing a layer of a semimetal in the range of 1 to 5 nm. A variety of semimetals may be deposited in step 104 to form a first liner, with antimony, bismuth, tellurium, and alpha-tin being desirable in some exemplary applications with their work functions between 4 eV and 5 eV and their low oxygen scavenging potential working to provide a scavenging barrier. In other cases, a first semimetal layer may be selected with a work function greater than about 5 eV.

Turning again to FIG. 1, the method 100 comprise a step 106 of forming a dielectric layer on or directly on the exposed, upper surface of the first semimetal layer (e.g., the first liner) formed in step 104. Again, any useful and well-known deposition technology may be used for step 106. Suitably, step 106 can include forming a metal oxide containing layer by means of an ALD process. Suitable ALD processes include a sequence of exposing the substrate to a metal precursor, exposing the substrate to a purge gas, exposing the substrate to an oxygen reactant, and exposing the substrate to a purge gas. Suitable metal precursors include metalorganic precursors and halides, and are known as such in the art. Suitable oxygen reactants include oxygen-containing gasses such as O₂, O₃, H₂O, and H₂O₂. The dielectric layer may be formed by a process that includes depositing a high-k or ultra-high k dielectric material such as hafnium oxide (HfO₂), doped HfO₂, hafnium zirconium oxide (HfZrO), doped HfZrO, or the like. In some cases, the dielectric layer comprises a high-k metal oxide material such as titanium oxide, zirconium oxide, aluminum oxide, barium-strontium-titanate, erbium oxide, hafnium silicate, lanthanum oxide, niobium oxide, lead-zirconium-titanate, strontium titanate, tantalum oxide, titanium oxide, zirconium oxide, or other high-k or ultra-high-k metal oxide (e.g., with k-values greater than about 40). For example, FIG. 5 illustrates a structure 500 including the substrate 202, the first electrode layer 302, the first semimetal layer 402, and the dielectric layer 502 disposed on or directly on the first semimetal layer 402. As illustrated in FIG. 5, the first semimetal layer 402 forms a first liner between the first electrode layer 302 and the dielectric layer 502.

In various embodiments the dielectric layer comprises a hafnium zirconium oxide (HfZrO) dielectric layer. In such embodiments the hafnium zirconium oxide layer (HfZrO) can be doped or undoped. The hafnium zirconium oxide (HfZrO) dielectric layer can be formed by performing one or super-cycles of an atomic layer deposition process. In some examples each super-cycle can comprise: performing one or more repetitions of a hafnium oxide sub-cycle (e.g., to deposit a HfO metal oxide component); and performing one or more repetitions of a zirconium oxide sub-cycle (e.g., to deposit a ZrO metal oxide component). Each of the hafnium oxide sub-cycles can be similar to the ALD processes described above, e.g., (a) introducing a hafnium precursor into the reaction chamber, and (b) introducing an oxygen reactant into the reaction chamber to react with the absorbed hafnium precursor. Likewise, each of the zirconium oxide sub-cycles can be similar to the ALD processes described above, e.g., (a) introducing a zirconium precursor into the reaction chamber, and (b) introducing an oxygen reactant into the reaction chamber to react with the absorbed zirconium precursor.

In some embodiments the stoichiometry of the hafnium zirconium oxide dielectric layer may be tuned by adjusting the ratio of the individual metal oxides, e.g., HfO and ZrO, in the HfZrO dielectric layer. In some embodiments a desired stoichiometry of the hafnium zirconium oxide dielectric layer may be achieved by selecting the number of times each sub-cycle (e.g., the hafnium oxide and the zirconium oxide sub-cycle) are repeated within a deposition super-cycle, for example to provide a desired Hf:Zr stoichiometry. In some embodiments, the deposited hafnium zirconium oxide dielectric layer can have a stoichiometry or elemental ratio (Hf:Zr) of 1:1, or 1:2 to 1:3, or 1:4, or 1:5, or 1:6, 1:7, or 1:8, or 1:9, or 1:10, or between 1:1 and 1:10. In other aspects, the dielectric layer is a hafnium oxide layer deposited by one or repetitions of the hafnium oxide sub-cycle. In yet other aspects, the dielectric layer is a zirconium oxide layer deposited by one or more repetitions of the zirconium oxide sub-cycle.

As illustrated in FIG. 5 the semiconductor stack 504 formed by steps 102, 104, and step 106 of method 100 comprises the first electrode layer 302 disposed on the substrate 202, the first semimetal layer 402 disposed on the first electrode layer 302, and the dielectric layer 502 (e.g., HfZrO) disposed on the first semimetal layer 402, where the first semimetal layer 402 forms a first liner sandwiched between the first electrode layer 302 and the dielectric layer 502.

In accordance with examples of the disclosure, the first electrode layer 302, the first semimetal layer 402, and the dielectric layer 502 can be formed by atomic layer deposition processes. In some embodiments the atomic layer deposition of the first electrode layer 302, the first semimetal layer 402, and the dielectric layer 502 can be performed within the same semiconductor processing apparatus.

In one aspect the semiconductor processing system utilized for performed method 100 may comprise a cluster tool comprising two or more reaction chambers, e.g., a first reaction chamber, a second reaction chamber, a third reaction chamber, and the like, and at least one of step 102, 104, 106 can be performed in the first reaction chamber, and/or at least one of step 102, 104, 106 can be performed in the second reaction chamber, and/or at least one of step 102, 104, and 106 can be performed in the third reaction chamber. When one step of method 100 is performed in a first reaction chamber, and a subsequent step of method 100 is performed in a second reaction chamber, the substrate 202 may be transferred between the first and second reaction chambers employing a transfer chamber having a controlled environment to prevent contamination of the layers formed on the substrate.

In another aspect the atomic layer deposition of the first electrode layer 302, the first semimetal layer 402, and the dielectric layer 502 can be performed within a first reaction chamber. In some aspects the forming of the semiconductor stack 504 can be completed without breaking vacuum in the reaction chamber, i.e., the steps 102, 104 and 106 can be performed sequentially one after another without transfer of the substrate to a second reaction chamber.

In another aspect the atomic layer deposition of the first electrode layer, the first metal oxide layer, and the dielectric layer, and the post-deposition thermal treatment of the first metal oxide layer are performed within a first reaction chamber without breaking vacuum.

Turning again to the method 100 illustrated in FIG. 1. In various embodiments method 100 comprises forming a second semimetal layer on the dielectric layer. In such embodiments the second semimetal layer can comprise all of the materials described above, formed by one or more of processes described with reference to step 104. For example, FIG. 6 illustrates a structure 600 which comprises the semiconductor stack 504 of FIG. 5 with the addition of the second semimetal layer 602 disposed on the dielectric layer 502.

In some embodiments the second semimetal layer comprises an elemental semimetal layer. In such embodiments the second semimetal layer may comprise antimony, bismuth, or tellurium. In such embodiments the second semimetal layer may be deposited by atomic layer deposition methods are described above.

In some embodiments forming the second semimetal layer can comprise depositing a second metal oxide layer on the dielectric layer by an atomic layer deposition process, and performing a post-deposition thermal treatment on the second metal oxide layer in a reducing atmosphere to convert the second metal oxide layer to the second semimetal layer. In such embodiments the second metal oxide layer can comprise a second tin oxide layer and the reduction of the second tin oxide layer by the post-deposition in the reducing atmosphere converts the second tin oxide layer to a second alpha-tin semimetal layer, i.e., the second semimetal layer comprises a second alpha-tin semimetal layer.

In various embodiment method 100 comprises forming a second electrode layer on the second semimetal layer (step 110). In such embodiments the second semimetal layer forms a second liner between the dielectric layer and the second electrode layer. For example, FIG. 7 illustrates a structure 700 which comprises the structure 600 of FIG. 6 with the addition of the second electrode layer 702 disposed on the dielectric layer 502, forming the semiconductor stack 704. As illustrated in FIG. 7 the semiconductor stack comprises a first semimetal layer 402 that forms a first liner between the first electrode layer 302 and the dielectric layer 502 and the second semimetal layer 602 forms a second liner between the dielectric layer 502 and the second electrode layer 702.

In some embodiment the second electrode layer (or top electrode layer) can be formed on or directly on an upper surface of the second semimetal layer. The second electrode layer is formed by depositing a thin layer of a conductive material on the substrate. In some embodiments the second electrode layer 702 comprises a titanium nitride (TiN). The conductive second electrode layer may be formed of other metals, conductive metal oxides, conductive metal silicides, conductive metal nitrides, and combinations thereof. In some embodiments, the second electrode layer may be formed by a deposition process, such as, but not limited, to PVD, CVD, and the like. In particular embodiments the second electrode layer is deposited by an atomic layer deposition process.

In one aspect the semiconductor processing system utilized for performed method 100 may comprise a cluster tool comprising two or more reaction chambers, e.g., a first reaction chamber, a second reaction chamber, a third reaction chamber, a fourth reaction chamber, a fifth reaction chamber and the like, and at least one of step 102, 104, 106, 108, and step 110 can be performed in the first reaction chamber, and/or at least one of step 102, 104, 106, 108, and 110can be performed in the second reaction chamber, and/or at least one of step 102, 104, 106, 108, and 110 can be performed in the third reaction chamber, and/or at least one of step 102, 104, 106, 108, and 110 can be performed in the fourth reaction chamber, and/or at least one of step 102, 104, 106, 108, and 110 can be performed in the fifth reaction chamber.

In another aspect the atomic layer deposition of the first electrode layer 302, the first semimetal layer 402, the dielectric layer 502, the second semimetal layer 602, and the second electrode layer 702 can be performed within a first reaction chamber. In some aspects the forming of the semiconductor stack 704 (FIG. 7) can be completed without breaking vacuum in the reaction chamber, i.e., the steps 102, 104, 106, 108, and 110 can be performed sequentially one after another without transfer of the substrate to a second reaction chamber.

In another aspect the atomic layer deposition of the first electrode layer, the first metal oxide layer, and the dielectric layer, and the post-deposition thermal treatment of the first metal oxide layer and the second metal oxide layer are performed within a first reaction chamber without breaking vacuum.

Turning again to FIG. 7 and semiconductor stack 704, the first semimetal layer 402 forming the first liner may have an average layer thickness less than or equal to 5 nm such as in the range of 0.5 to 5 nm. In addition, the second semimetal layer 602 forming the second liner may have an average layer thickness of less than or equal to 5 nm such as in the range of 0.5 to 5 nm. In addition, the dielectric layer 502 (e.g., HfO, ZrO, or HfZrO) may have an average layer thickness of less than or equal to 5 nm such as in the range of 0.5 to 5 nm with dielectric constant greater than 30, or greater than 40, or greater than 50. In some embodiments the dielectric layer 502 comprises a hafnium zirconium oxide dielectric layer having an average layer thickness of less than or equal to 5 nm such as in the range of 0.5 to 5 nm with dielectric constant greater than 30, or greater than 40, or greater than 50, and stoichiometry (Hf:Zr) between 1:1 and 1:5, or between 1:1 and 1:4, or between 1:3, or between 1:2.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Reference throughout this specification to features, advantages, or similar language does not imply that all of the features and advantages that may be realized with the present disclosure should be or are in any single embodiment of the invention. Rather, language referring to the features and advantages is understood to mean that a specific feature, advantage, or characteristic described in connection with an embodiment is included in at least one embodiment of the subject matter disclosed herein. Thus, discussion of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S. C. 112(f) unless the element is expressly recited using the phrase “means for.”The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of,” when used with a list of items, means different combinations of one or more of the listed items may be used and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Any reference to attached, fixed, connected or the like may include permanent, removable, temporary, partial, full and/or any other possible attachment option. Additionally, any reference to without contact (or similar phrases) may also include reduced contact or minimal contact. In the above description, certain terms may be used such as “up,” “down,” “upper,” “lower,” “horizontal,” “vertical,” “left,” “right,” and the like. These terms are used, where applicable, to provide some clarity of description when dealing with relative relationships. But these terms are not intended to imply absolute relationships, positions, and/or orientations. For example, with respect to an object, an “upper” surface can become a “lower” surface simply by turning the object over. Nevertheless, it is still the same object.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and sub combinations of the various systems, components, and configurations, and other features, functions, acts, and/or properties disclosed herein, as well as any and all equivalents thereof.

What is claimed is:

1. A method of forming a semiconductor stack on a substrate for use in metal-insulator-metal (MIM) capacitors, the method comprising:
forming a first electrode layer comprising a conductive material on the substrate;
forming a first semimetal layer on the first electrode layer; and
forming a dielectric layer on the first semimetal layer,
wherein the first semimetal layer forms a first liner between the first electrode layer and the dielectric layer.

2. The method of claim 1, wherein the first semimetal layer is an elemental semimetal layer.

3. The method of claim 2, wherein the first electrode layer, the first semimetal layer, and the dielectric layer are formed by atomic layer deposition.

4. The method of claim 3, wherein the atomic layer deposition of the first electrode layer, the first semimetal layer, and the dielectric layer is performed within the same semiconductor processing apparatus.

5. The method of claim 4, wherein the atomic layer deposition of the first electrode layer, the first semimetal layer, and the dielectric layer is performed within a first reaction chamber without breaking vacuum.

6. The method of claim 5, wherein the first semimetal layer comprises antimony, bismuth, or tellurium.

7. The method of claim 1, wherein forming the first semimetal layer comprises:
depositing a first metal oxide layer on the first electrode layer by an atomic layer deposition process; and
performing a post-deposition thermal treatment on the first metal oxide layer in a reducing atmosphere to convert the first metal oxide layer to the first semimetal layer.

8. The method of claim 7, wherein the atomic layer deposition of the first electrode layer, the first metal oxide layer, and the dielectric layer, and the post-deposition thermal treatment of the first metal oxide layer are performed within a first reaction chamber without breaking vacuum.

9. The method of claim 8, wherein the first semimetal layer comprises alpha-tin (α-Sn).

10. The method of claim 1, further comprising:
forming a second semimetal layer on the dielectric layer; and
forming a second electrode layer on the second semimetal layer,
wherein the second semimetal layer forms a second liner between the dielectric layer and the second electrode layer.

11. The method of claim 10, wherein the first electrode layer, the first semimetal layer, the dielectric layer, the second semimetal layer, and the second semimetal layer are formed by atomic layer deposition processes in a first reaction chamber without breaking vacuum.

12. The method of claim 11, wherein the second semimetal layer comprises an elemental semimetal layer.

13. The method of claim 12, wherein the second semimetal layer comprises antimony, bismuth, or tellurium.

14. The method of claim 13, wherein forming the second semimetal layer further comprises:
depositing a second metal oxide layer on the dielectric layer by an atomic layer deposition process; and
performing a post-deposition thermal treatment on the second metal oxide layer in a reducing atmosphere to convert the second metal oxide layer to the second semimetal layer.

15. The method of claim 1, where the dielectric layer comprises a hafnium zirconium oxide (HfZrO) dielectric layer.

16. The method of claim 15, where the hafnium zirconium oxide (HfZrO) dielectric layer is formed by performing one or super-cycles of an atomic layer deposition process, each super-cycle comprising:
performing one or more repetitions of a hafnium oxide sub-cycle; and
performing one or more repetitions of a zirconium oxide sub-cycle,
wherein the hafnium zirconium oxide (HfZrO) dielectric layer has a stoichiometry (Hf:Zr) between 1:1 and 1:5.

17. A method of forming a semiconductor stack on a substrate for use in metal-insulator-metal (MIM) capacitors, the method comprising:
depositing a first electrode layer comprising a conductive material on the substrate;
forming a first semimetal layer directly on the first electrode layer;
depositing a hafnium zirconium oxide (HfZrO) dielectric layer directly on the first semimetal layer;
forming a second semimetal layer directly on the hafnium zirconium oxide (HfZrO) dielectric layer; and
depositing a second electrode layer directly on the second semimetal layer,
wherein the first semimetal layer forms a first liner between the first electrode layer and the hafnium zirconium oxide dielectric layer, and the second semimetal layer forms a second liner between the hafnium zirconium oxide (HfZrO) dielectric layer and the second electrode layer.

18. The method of claim 17, wherein the first semimetal layer and the second semimetal layer comprise a material selected from the group consisting of antimony, bismuth, tellurium, and alpha-tin (α-Sn).

19. The method of claim 18, wherein the semiconductor stack is formed by atomic layer deposition processes within a first reaction chamber without breaking vacuum.

20. The method of claim 19, wherein the first semimetal layer and the second semimetal layer are alpha-tin (α-Sn) are formed by:
depositing a first tin oxide layer on the first electrode layer by an atomic layer deposition process;
depositing a second tin oxide layer on the hafnium zirconium dielectric layer; and
performing a post-deposition thermal treatment on the first tin oxide layer and second tin oxide layer in a reducing atmosphere to convert the first tin oxide layer and a first alpha-tin (first α-Sn) semimetal layer and to convert the second tin oxide layer to a second alpha-tin (second α-Sn) semimetal layer.
